(19) United States
(12) Patent Application Publication
(10) Pub. No.: US 2002/0133314 A1
(43) Pub. Date: Sep. 19, 2002

(54) Notification method and notification system of operation information of apparatus, and computer readable storage medium

(75) Inventor: Yasuo Shibata, Ina-shi (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: Olympus Optical Co., Ltd, Tokyo (JP)

(21) Appl. No.: 10/137,047

(22) Filed: May 1, 2002

Related U.S. Application Data
(63) Continuation of application No. PCT/JP01/07745, filed on Sep. 6, 2001.

(30) Foreign Application Priority Data
Sep. 8, 2000 (JP) 2000-273848

(51) Int. Cl. G21C 17/00; G06F 15/00; G06F 11/30; H03K 19/003; H05K 10/00; H02H 3/05; H04B 1/74; H04L 1/22

(52) U.S. Cl. 702/184; 714/57

(57) ABSTRACT

A notification method of operation information of an apparatus, comprising adding at least one information of information on a user of an object apparatus, information of an operation procedure of the object apparatus concerning a problem having occurred in the object apparatus, information of an operation history of the object apparatus, information in which an operation condition of the object apparatus is set, and information of an existing image of the object apparatus to message information indicating a content of transmission information, and transmitting the at least one information to a terminal apparatus of a pre-designated transmission destination from a terminal apparatus of a transmitter via a communication line.

### CROSS-REFERENCE TO RELATED APPLICATIONS

This is a Continuation Application of PCT Application No. PCT/JP01/07745, filed Sep. 6, 2001, which was not published under PCT Article 21(2) in English.

This application is based upon and claims the benefit of priority from the prior Japanese Patent Application No. 2000-273848, filed Sep. 8, 2000, the entire contents of which are incorporated herein by reference.

### BACKGROUND OF THE INVENTION

1. Field of the Invention

The present invention relates to a notification method and notification system of operation information of an apparatus, in which a maintenance manager side is notified of the operation information of the apparatus, for example, in order to diagnose/analyze failures of various apparatuses operating on a customer side.

2. Description of the Related Art

Examples of a manufacturing sales company include a company which designs, manufactures, and sells various apparatuses such as a visual examination apparatus for performing a visual examination of dust, foreign particles, and the like deposited on a glass substrate or a color filter of a flat panel display (FPD), and the surface of a large-sized substrate such as a semiconductor wafer. In this manufacturing sales company, after the various apparatuses are sold to a customer, and a problem occurs in the apparatus operating for the customer, it receives a complaint about the occurrence of the problem from the customer and is requested to promptly solve the problem.

When such problems occur, the maintenance manager side of the manufacturing sales company requires a large amount of information on the apparatus, such as the error content and operation history (log) of the apparatus, the situation of the apparatus, and a file (ini file) for setting the condition of the operation of the apparatus in order to diagnose/analyze the failure of the apparatus with the problem having occurred therein. Therefore, the maintenance manager of the manufacturing sales company inquires of the customer about these necessary information by telephone.

The customer having received the inquiry has to perform operations of storing the log of the apparatus in a floppy disk and sending the disk to the manufacturing sales company, making a note of the content of error dialog of the apparatus and sending the note to the manufacturing sales company via facsimile, checking the setting of the operation condition of the apparatus, checking the manufacture number of a personal computer connected to the apparatus, and the like.

When the customer side has securely performed these operations and sends each information to the manufacturing sales company, the company can sufficiently analyze the apparatus with the problem having occurred therein. However, the customer side is busy handling the apparatus with the problem having occurred therein, feels bothered with these operations, and cannot make a sufficient response in some case. Therefore, the manufacturing sales company side cannot obtain the information for investigating the cause of the problem, and a repairman is sent to the customer.

Moreover, expertise is necessary for performing the operations of storing the log in the floppy disk, checking the content of the error dialog of the apparatus, checking the setting of the operation condition of the apparatus, and the like. Therefore, a person in charge on the customer side does not know a method of handling the problem in some case, and is too busy handling the problem to respond to the manufacturing sales company in the other case.

In the above-described situation, the customer side busy handling the problem requests that the manufacturing sales company quickly repair the apparatus with the problem having occurred therein. Moreover, on the manufacturing sales company side, when the cause of the problem is not known, the cause is predicted, necessary tools, and repair components are prepared and the repairman is sent. If the prediction proves wrong, the problem cannot be handled in some case.

### BRIEF SUMMARY OF THE INVENTION

An object of the present invention is to provide a notification method and notification system of operation information of an apparatus, in which information required by a maintenance manager for the apparatus with a problem having occurred therein and information on a customer can be transmitted to the maintenance manager as a pre-designated transmission destination without giving any burden on a customer side, the maintenance manager can quickly obtain accurate information on the apparatus with the problem having occurred therein by the information transmitted from the customer, and a period for solving the problem can be shortened.

Another object of the present invention is to provide a storage medium readable by a computer, which stores a program for transmitting the information on the apparatus with the problem having occurred therein and the information on the customer to the maintenance manager as the pre-designated transmission designation without giving any burden to the customer.

A notification method of operation information of apparatus according to the present invention comprises: adding at least one information of information on a user of an object apparatus, information of an operation procedure of the object apparatus concerning a problem having occurred in the object apparatus, information of an operation history of the object apparatus, information in which an operation condition of the object apparatus is set, and information of an existing image of the object apparatus to message information indicating a content of transmission information; and transmitting the at least one information to a terminal apparatus of a pre-designated transmission destination from a terminal apparatus of a transmitter via a communication line.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a diagram showing a total constitution of a notification system of operation information of an apparatus according to an embodiment of the present invention.

FIG. 2 is a diagram showing a main screen displayed in the notification system according to the embodiment of the present invention.

FIG. 3 is a diagram showing a dialog box of mail setting displayed in the notification system according to the embodiment of the present invention.

FIG. 4 is a diagram showing a dialog box of apparatus information setting displayed in the notification system according to the embodiment of the present invention.

FIG. 5 is a flowchart showing an operation procedure of a personal computer by support mail software according to the embodiment of the present invention.

FIG. 6 is a diagram showing the main screen displayed in the notification system according to the embodiment of the present invention.

FIG. 7 is a flowchart showing the operation procedure of the personal computer by support mail software according to the embodiment of the present invention.

### DETAILED DESCRIPTION OF THE INVENTION

Embodiments of the present invention will be described hereinafter with reference to the drawings.

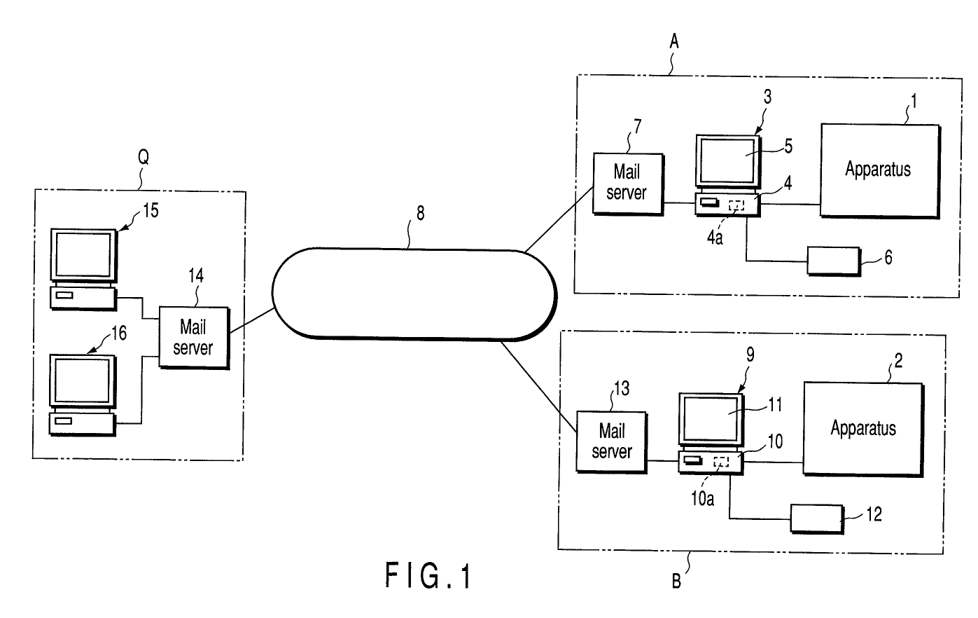

FIG. 1 is a diagram showing a total constitution of a notification system of operation information of an apparatus according to a first embodiment of the present invention. In FIG. 1, apparatuses 1, 2 purchased from a manufacturing sales company (maintenance manager) Q are mounted on the side of a plurality of customers (users) A, B, and operate. These apparatuses 1, 2 are visual examination apparatuses which perform visual examination of dust, foreign particles, and the like depositing, for example, to a glass substrate and color filter of a flat panel display (FPD), and large-sized substrate surfaces such as a semiconductor wafer.

For the customer A, the operation state of the apparatus 1 is controlled and monitored by a personal computer 3 as a terminal apparatus. The personal computer 3 is constituted of a computer main body 4 and liquid crystal display 5, and the computer main body 4 is connected to an image pick-up apparatus 6 for picking up an image of the apparatus 1. The computer main body 4 is connected to a communication network (telephone line, exclusive line, Internet, and the like) 8 via a mail server 7.

In a storage unit (hard disk) 4a incorporated in the computer main body 4 of the personal computer 3, as described later, a program (a function by this program will hereinafter be referred to as a support mail) for notifying information (log) of an operation history of the apparatus 1, information (ini file) of an operation condition, and the like to a mail server 14 of the maintenance manager Q as a pre-designated transmission destination is stored.

In the mail server 7, a Simple Mail Transfer Protocol (SMTP) server of a protocol for use in mail transmission based on TCP/IP on the Internet is used.

For the customer B, similarly as the customer A, the operation state of the apparatus 2 is controlled and monitored by a personal computer 9 as the terminal apparatus. The personal computer 9 is constituted of a computer main body 10 and liquid crystal display 11, and the computer main body 10 is connected to an image pick-up apparatus 12 for picking up the image of the apparatus 2. The image pick-up apparatus 12 may be a CCD camera for examination, for use in photographing the surfaces of various substrates in a macro or micro manner, subjecting the photographed information to an image processing, and detecting a defect, or a monitor camera for monitoring the operation of the apparatus. The computer main body 10 is connected to the communication network 8 via a mail server of SMTP 13 similar to the mail server 7.

In a storage unit (hard disk) 10a incorporated in the computer main body 10 of the personal computer 9, as described later, a program of the support mail for notifying the operation history (log) of the apparatus 2, and the like to the mail server 14 of the maintenance manager Q as the pre-designated transmission destination is stored.

Additionally, the apparatuses 1, 2 are installed in the customers A, B, respectively. However, when a plurality of apparatuses 1, 2 are installed, respective personal computers for controlling and monitoring the respective operation states of these apparatuses are connected to the mail servers 7, 13 of the customers A, B.

On the other hand, on the side of the maintenance manager Q, the mail server of SMTP 14 is connected to the communication network 8. When the mail server 14 is used only for receiving the information, a post office protocol (POP) server may be used.

The mail server 14 is connected to a plurality of personal computers as receiving apparatuses, such as two personal computers 15, 16. The mail server 14 has a function of receiving the information transmitted from the respective customers A, B, and transferring these information to the respective personal computers 15, 16. These personal computers 15, 16 are installed for a person in charge who maintains/manages the apparatuses 1, 2 installed in the customers A, B, respectively.

The function of the support mail of the personal computers 3, 9 on the side of the customers A, B will next be described. These personal computers 3, 9 have the same support mail function. In the following, the function of the personal computer 3 of the customer A will be described, and the description of the function of the personal computer 9 of the customer B is omitted.

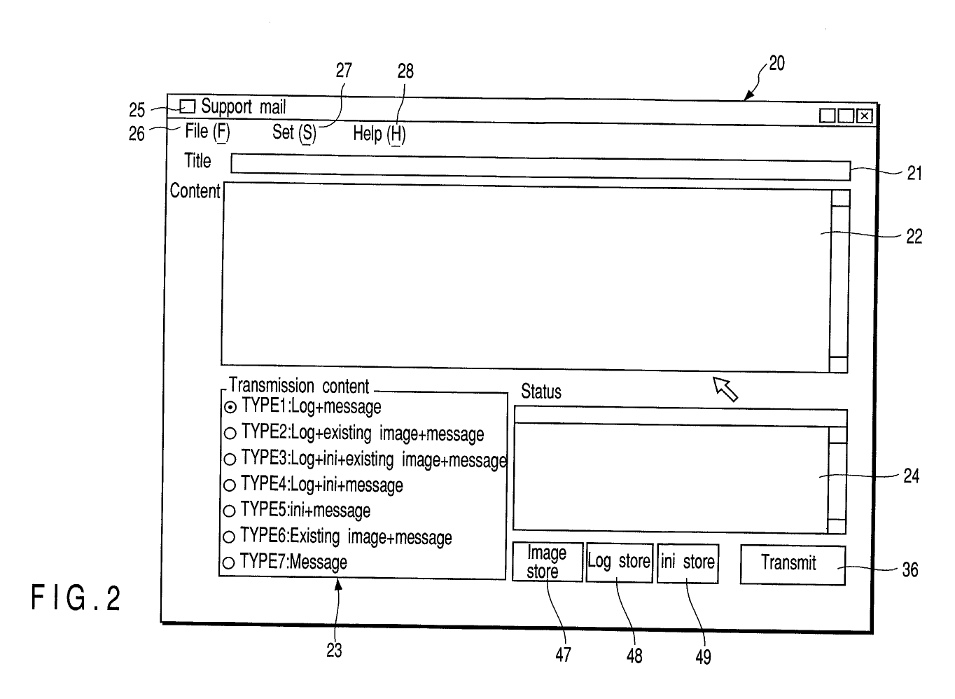

FIG. 2 is a diagram showing a main screen displayed in the notification system. In the computer main body 4 of the personal computer 3 of the customer A, when the built-in support mail software is started, a main screen 20 for urging input of each piece of information is displayed in the liquid crystal display 5 as shown in FIG. 2.

According to the content of the main screen 20, a user performs an input operation by a mouse or a keyboard (not shown) connected to the computer main body 4. Then, the computer main body 4 adds information on the user of the apparatus 1 and information on the apparatus 1 and personal computer 3 to message information indicating the content of transmission information. Furthermore, the computer main body 4 attaches optional information selected from the information (log) of the operation history of the apparatus 1, information (ini file) having the operation condition of the apparatus 1 set therein, and image information (such as an operation screen of the apparatus, and an image of a defective portion) picked up by the image pick-up apparatus 6 to the message information. Moreover, the computer main body 4 transmits these information to the mail server 14 of the maintenance manager Q as the pre-designated transmission destination.

As shown in FIG. 2, the main screen 20 displays a title box 21 for inputting a title of a mail, a content box 22 for inputting message information (the text of the mail) indicating the content of the transmission information, and a transmission content 23 indicating each item so as to select the transmission content (attached file) of the mail.

In the transmission content of the mail 23, respective types (TYPES 1 to 7) of combinations of the log of the apparatus 1, ini file of the apparatus 1, image information of the present state (such as a problem) of the apparatus 1, and the like are displayed for respective items. “TYPE 1” indicates ‘log+message information’, in which the log is compressed, attached to the message information, and transmitted. “TYPE 2” indicates ‘log+existing image+message information’, in which the existing image is taken in and compressed, the log is then compressed, and they are attached to the message information and transmitted. “TYPE 3” indicates ‘log+ini+existing image+message information’, in which the existing image is taken in and compressed, the log and ini file are then compressed, and they are attached to the message information and transmitted. “TYPE 4” indicates ‘log+ini+message information’, in which the log and ini file are compressed, attached to the message information and transmitted. “TYPE 5” indicates ‘ini+message information’, in which the ini file is compressed, attached to the message information and transmitted. “TYPE 6” indicates ‘existing image+message information’, in which the existing image is taken in and compressed, attached to the message information and transmitted. “TYPE 7” indicates the message information, and only the message information is transmitted.

Additionally, the existing image, log, and ini file have file names ‘year month day hour minute second cap.lzh’, ‘year month day hour minute second log.lzh’, and ‘year month day hour minute second ini.lzh’, respectively, when compressed.

Moreover, a status box 24 showing various messages is displayed in the main screen 20. In a menu bar 25 of the main screen 20, a file menu 26, set menu 27, and help menu 28 showing version information are displayed. The file menu 26 is used to end a support mail function, and the set menu 27 is used to set the mail and apparatus information.

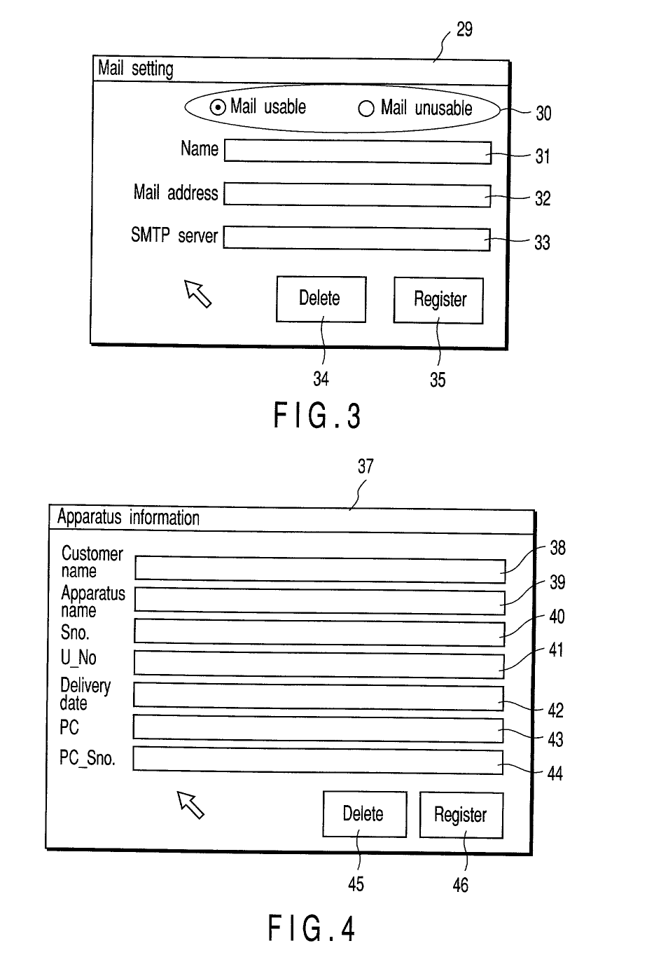

FIG. 3 is a diagram showing a dialog box of mail setting displayed in the notification system. When the mail setting of the set menu 27 is selected and clicked by the operation of the mouse or the keyboard by the user, the computer main body 4 of the personal computer 3 displays a dialog box 29 of the mail setting as a sub screen shown in FIG. 3 in the liquid crystal display 5.

The dialog box 29 of the mail setting displays an item 30 for setting a mail usable or a mail unusable, a name box 31 for inputting a user's name, a mail address box 32 for inputting a user's mail address, an SMTP server box 33 for setting the mail server 7, a delete button 34 for returning to the main screen 20 shown in FIG. 2, and a register button 35 for storing the set information. Additionally, the ‘mail unusable’ is set in the item 30. In this case, even when a transmit button 36 shown in FIG. 2 is pressed as described later, an error is displayed and the mail is not transmitted.

FIG. 4 is a diagram showing a dialog box of apparatus information settings displayed in the notification system. When the setting of apparatus information of the set menu 27 is selected and clicked by the operation of the mouse or the keyboard by the user, the computer main body 4 of the personal computer 3 displays a dialog box 37 of the apparatus information setting as the sub screen shown in FIG. 4 in the liquid crystal display 5.

The dialog box 37 of the apparatus information setting displays a customer name box 38 for setting the user name (customer A), an apparatus name box 39 for setting a formal name of the apparatus 1, a manufacture number box (Sno) 40 for setting a manufacture number of the apparatus 1, a user apparatus name box (U. No) 41 for setting the name of the apparatus 1 determined by the user (customer A), a delivery date box 42 for setting a delivery date of the apparatus 1, a personal computer (PC) box 43 for setting the name of the personal computer 3, a PC number box 44 for setting the manufacture number of the personal computer 3, a delete button 45 for returning to the main screen 20 shown in FIG. 2, and a register button 46 for storing the set information.

There will be described the main screen 20 shown in FIG. 2. In the lower part of the main screen 20, an image store button 47, log store button 48, and ini store button 49 are displayed. When the user selects/operates the image store button 47, log store button 48, and ini store button 49 by the mouse or the keyboard, the image information, log, and ini file picked up by the image pick-up apparatus 6 are individually stored in an internal memory of the personal computer 3.

Additionally, the existing image, log, and ini file have the file names ‘year month day hour minute second cap.lzh’, ‘year month day hour minute second log.lzh’, and ‘year month day hour minute second ini.lzh’, respectively, when compressed.

The transmit button 36 transmits the title of the mail set on the main screen 20, the message information indicating the content of the transmission information, any type (TYPES 1 to 7) of the combination of the log of the apparatus 1, ini file of the apparatus 1, and existing image information of the apparatus 1 as an attached file of the message information, the information set in the dialog box 29 of the mail setting, and the information set in the dialog box 37 of the apparatus information setting to the mail server 14 of the maintenance manager Q.

The respective personal computers 15, 16 on the side of the maintenance manager Q display the information transferred from the mail server 14, that is, the title of the mail, the message information indicating the content of the transmission information, the information “TYPES 1 to 7” of the combinations of the log of the apparatus 1, ini file of the apparatus 1, and existing image information of the apparatus 1 as the attached file of the message information, the information on the respective customers A, B, and the information on the apparatuses 1, 2 installed in these customers A, B in the liquid crystal display.

An action of the notification system constituted as described above will next be described. The operation state of the apparatus 1 is controlled and monitored by the personal computer 3. The computer main body 4 of the personal computer 3 has the information (ini file) of the operation condition of the apparatus 1 set therein, controls/monitors the apparatus 1, and collects the information (log) of the operation history of the apparatus 1.

When a certain problem (trouble, defect) occurs in the apparatus 1 in the operating state of the apparatus 1 in this manner, the user starts the support mail software of the personal computer 3 in order to repair the problem of the apparatus 1 at an early stage.

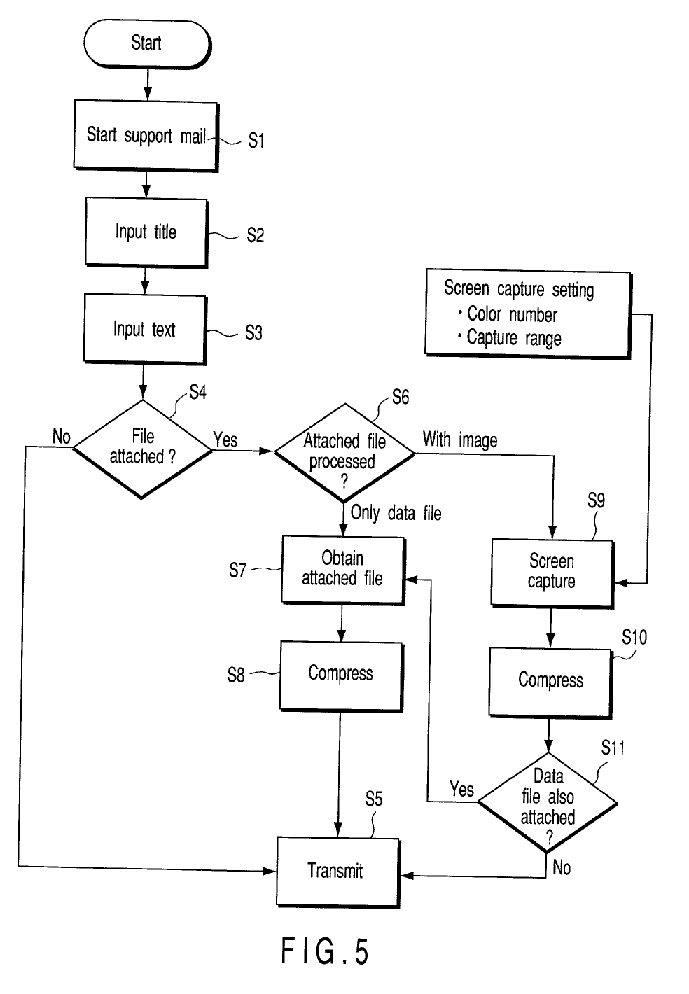

FIG. 5 is a flowchart showing an operation procedure of the personal computer 3 by the support mail software. In the personal computer 3, when the support mail software is started in step S1, the main screen 20 shown in FIG. 2 is displayed in the liquid crystal display 5.

Here, when the mail setting shown in FIG. 3 and the setting of the apparatus information shown in FIG. 4 are already ended in the support mail software, the personal computer 3 advances to the next step S2 to input the title. On the other hand, when these mail setting and apparatus information setting are not done yet, the user performs these settings.

That is, when the mail setting of the set menu 27 is selected and clicked in the main screen 20 by the operation of the mouse or the keyboard by the user, the personal computer 3 displays the dialog box 29 of the mail setting as the sub screen shown in FIG. 3 in the liquid crystal display 5.

Subsequently, in the dialog box 29 of the mail setting, by the operation of the mouse or the keyboard by the user, “mail usable” or “mail unusable” is selected in the item 30, the user's name is inputted in the name box 31, the user's mail address is inputted in the mail address box 32, and the mail server 7 is set in the SMTP server box 33. Moreover, when the content of the inputted mail setting is satisfactory, the user presses the register button 35 by the operation of the mouse or the keyboard. Thereby, the personal computer 3 registers the information of the mail setting in the internal memory. When the registration is completed, the display of the dialog box 29 disappears and returns to the main screen 20 shown in FIG. 2 in the liquid crystal display 5.

Moreover, when the setting of the apparatus information of the set menu 27 is selected and clicked in the main screen 20 by the operation of the mouse or the keyboard by the user, the personal computer 3 displays the dialog box 37 of the setting of the apparatus information as the sub screen shown in FIG. 4 in the liquid crystal display 5.

Subsequently, in the dialog box 37 of the setting of the apparatus information, by the operation of the mouse or the keyboard by the user, the user name (customer A) is set in the customer name box 38, the formal name of the apparatus 1 is set in the apparatus name box 39, the manufacture number of the apparatus 1 is set in the manufacture number box (Sno) 40, the name of the apparatus 1 determined by the user (customer A) is set in the user apparatus name box (U. No) 41, the delivery date of the apparatus 1 is set in the delivery date box 42, the name of the personal computer 3 is set in the personal computer (PC) box 43, and the manufacture number of the personal computer 3 is set in the PC number box 44. Moreover, when the contents of these inputted setting of the apparatus information are satisfactory, the user presses the register button 46 by the operation of the mouse or the keyboard. Thereby, the personal computer 3 registers the information of the setting of the apparatus information in the internal memory. When the registration is completed, the display of the dialog box 37 disappears and returns to the main screen 20 shown in FIG. 2 in the liquid crystal display 5. In the following, it is assumed that “mail usable” is set in the item 30.

Subsequently, in the personal computer 3, the title of the mail is inputted in the title box 21 in the main screen 20 by the operation of the mouse or the keyboard by the user, and further the message information (the text of the mail) indicating the content of the transmission information is inputted in the content box 22.

Moreover, in the main screen 20, by the operation of the mouse or the keyboard by the user, one of the types “TYPE 1 to 7” consisting of the combinations of the message information, log of the apparatus 1, ini file of the apparatus 1, and existing image information of the apparatus 1 is selected in the transmission content of the mail 23.

As described above, when the title of the mail and message information (the text of the mail) are inputted, and the type of the transmission content of the mail is selected, the personal computer 3 temporarily stores the title in the internal memory in step S2, and temporarily stores the message information (the text of the mail) in the internal memory in the subsequent step S3.

Subsequently, the personal computer 3 judges in step S4 whether or not there is a file to be attached in TYPES 1 to 7 selected in the transmission content of the mail 23. As a result of the judgment, the transmission content of the mail is of the type “TYPE 7” and includes only the message information, then the personal computer 3 judges that there is no file to be attached, and waits until the transmit button 36 is pressed.

Moreover, when the user presses the transmit button 36 by the operation of the mouse or the keyboard, in step S5 the personal computer 3 automatically adds the user's name, user's mail address, and information of the setting of the mail server 7 set in the dialog box 29 of the mail setting shown in FIG. 3, and the user name (customer A), formal name of the apparatus 1, manufacture number of the apparatus 1, name of the apparatus 1 determined by the user (customer A), delivery date of the apparatus 1, name of the personal computer 3, and manufacture number of the personal computer 3 set in the dialog box 37 of the setting of the apparatus information shown in FIG. 4 to the title of the mail inputted in the title box 21 and the message information (the text of the mail) indicating the content of the transmission information inputted in the content box 22, and transmits these information to the mail server 14 on the side of the maintenance manager Q. Thereby, the information is sent to the mail server 14 of the maintenance manager Q side from the mail server 7 via the communication network 8.

The mail server 14 transfers the received information to the respective personal computers 15, 16. These personal computers 15, 16 display the information transferred from the mail server 14, that is, the title of the mail, the message information (the text of the mail) indicating the content of the transmission information, the user's name, the user's mail address, and the information of the setting of the mail server 7, as well as the user name (customer A), the formal name of the apparatus 1, the manufacture number of the apparatus 1, the name of the apparatus 1 determined by the user (customer A), the delivery date of the apparatus 1, the name of the personal computer 3, and the manufacture number of the personal computer 3 in the respective liquid crystal displays.

Therefore, the respective persons in charge of maintenance/management of the apparatus 1 installed at customer A's site can analyze the problem of the apparatus 1 from the respective information displayed in the liquid crystal displays of the personal computers 15, 16.

On the other hand, as a result of the judgment of the step S4, when the transmission content of the mail is of the type “TYPES 1 to 6” and there is a file to be attached, the personal computer 3 shifts to step S6, and judges whether the file to be attached is only a data file (the information (log) of the operation history of the apparatus 1, the ini file of the apparatus 1), or whether there is image information. As a result of the judgment, when the transmission content of the mail is of the type “TYPE 1”, and includes ‘log+message information’, the personal computer 3 obtains the information (log) of the operation history of the apparatus 1 as the attached file in step S7.

Subsequently, in step S8, the personal computer 3 compresses the information (log) of the operation history of the apparatus 1, and attaches this information to the message information (the text of the mail). Additionally, the information (log) of the operation history of the apparatus 1 has the file name ‘year month day hour minute second log.lzh’, when compressed.

Next, when the user presses the transmit button 36 by the operation of the mouse or the keyboard, in the step S5 the personal computer 3 automatically adds the user's name, user's mail address, and information of the setting of the mail server 7 set in the dialog box 29 of the mail setting shown in FIG. 3, and the user name (customer A), formal name of the apparatus 1, manufacture number of the apparatus 1, name of the apparatus 1 determined by the user (customer A), delivery date of the apparatus 1, name of the personal computer 3, and manufacture number of the personal computer 3 set in the dialog box 37 of the setting of the apparatus information shown in FIG. 4 to the title of the mail, the message information (the text of the mail), and the compressed information (log) of the operation history of the apparatus 1, and transmits these information to the mail server 14 on the side of the maintenance manager Q. Thereby, the information is sent to the mail server 14 of the maintenance manager Q side from the mail server 7 via the communication network 8.

The mail server 14 transfers the received information to the respective personal computers 15, 16. These personal computers 15, 16 display the information transferred from the mail server 14, that is, the title of the mail, the message information (the text of the mail) indicating the content of the transmission information, the information (log) of the operation history of the apparatus 1, the user's name, the user's mail address, and the information of the setting of the mail server 7, as well as the user name (customer A), the formal name of the apparatus 1, the manufacture number of the apparatus 1, the name of the apparatus 1 determined by the user (customer A), the delivery date of the apparatus 1, the name of the personal computer 3, and the manufacture number of the personal computer 3 in the respective liquid crystal displays.

Therefore, the respective persons in charge of maintenance/management of the apparatus 1 installed at customer A's site analyze the problem of the apparatus 1 from the respective information displayed in the liquid crystal displays of the personal computers 15, 16.

Moreover, as a result of the judgment of the step S6, when the transmission content of the mail is of the type “TYPE 4” and includes ‘log+ini+message information’, the personal computer 3 obtains the information (log) of the operation history of the apparatus 1 and the ini file of the apparatus 1 as the attached files in step S7, and compresses these attached files and attaches the files to the message information (the text of the mail) in step S8.

Furthermore, as a result of the judgment of the step S6, when the transmission content of the mail is of the type “TYPE 5” and includes ‘ini+message information’, the personal computer 3 obtains the ini file of the apparatus 1 as the attached file in the step S7, and compresses the attached file and attaches the file to the message information (the text of the mail) in the step S8.

Subsequently in the step S5, similarly as described above, each information is sent to the mail server 14 of the maintenance manager Q side from the mail server 7 via the communication network 8. Moreover, the mail server 14 transfers the received information to the respective personal computers 15, 16. These personal computers 15, 16 display the information in the liquid crystal displays, respectively.

On the other hand, as a result of the judgment of the step S6, when the transmission content of the mail is of the type “TYPE 2” and includes ‘log+existing image+message information’, the file to be attached includes the image information. Therefore, the personal computer 3 shifts to step S9, receives the operation input of the mouse or the keyboard by the user, and sets a color number and capture range as a screen capture.

Subsequently, the personal computer 3 compresses the information of the existing image taken from the image pick-up apparatus 6 in step S10. Subsequently, the personal computer 3 judges in step S11 whether or not there is a data file to be attached. With the transmission content of the mail of the type “TYPE 2”, since there is the data file to be attached, the personal computer shifts to step S7, and obtains the information (log) of the operation history of the apparatus 1 and the information of the existing image as the attached files.

Subsequently, the personal computer 3 compresses the information (log) of the operation history of the apparatus 1, and attaches the information and the pre-compressed information of the existing image to the message information (the text of the mail) in step S8. Additionally, the existing image, log, and ini file have the file names ‘year month day hour minute second cap.lzh’, ‘year month day hour minute second log.lzh’, and ‘year month day hour minute second ini.lzh’, respectively, when compressed.

Next, when the user presses the transmit button 36 by the operation of the mouse or the keyboard, in the step S5 the personal computer 3 automatically adds the respective information set in the dialog box 29, and the respective information set in the dialog box 37 to the title of the mail, the message information (the text of the mail), the compressed information (log) of the operation history of the apparatus 1, and the information of the existing image, and transmits the information to the mail server 14 of the maintenance manager Q side. Thereby, the information is sent to the mail server 14 of the maintenance manager Q side from the mail server 7 via the communication network 8.

The mail server 14 transfers the received information to the respective personal computers 15, 16. These personal computers 15, 16 display the information transferred from the mail server 14 in the respective liquid crystal displays.

Moreover, as a result of the judgment of the step S6, when the transmission content of the mail is of the type “TYPE 3” and includes ‘log+ini+existing image+message information’, the ini file of the apparatus 1 is added as the attached file to the processing for the above-described “TYPE 2”.

Furthermore, as a result of the judgment of the step S6, when the transmission content of the mail is of the type “TYPE 6” and includes ‘existing image+message information’, the personal computer 3 shifts to step S9, sets the screen capture, and compresses the information of the existing image in step S10. Subsequently, since there is no data file to be attached in step S11, the personal computer 3 advances to the step S5.

Next, when the user presses the transmit button 36 by the operation of the mouse or the keyboard, in the step S5 the personal computer 3 automatically adds the respective information set in the dialog box 29, and the respective information set in the dialog box 37 to the title of the mail, the message information (the text of the mail), and the information of the existing image, and transmits these information to the mail server 14 of the maintenance manager Q side. Thereby, the information is sent to the mail server 14 of the maintenance manager Q side from the mail server 7 via the communication network 8.

The mail server 14 transfers the received information to the respective personal computers 15, 16. These personal computers 15, 16 display the information transferred from the mail server 14 in the respective liquid crystal displays.

Additionally, when the customer A desires to store the transmitted existing image, log, or ini file, the user presses the image store button 47, the log store button 48, or the ini store button 49 in the main screen 20 by the clicking of the mouse or the selection operation by the keyboard. Thereby, the existing image, the log file, or the ini file is stored in the internal memory of the personal computer 3.

As described above, in the first embodiment, at least the information on the user of the apparatus 1 of the customer A and the information on the apparatus 1 are added to the message information indicating the content of the transmission information. Furthermore, the optional information selected from the information (log) of the operation history of the apparatus 1, the information (ini file) having the operation condition of the apparatus 1 set therein, and the information of the existing image of the apparatus 1 is attached. The information is transmitted to the maintenance manager Q as the pre-designated transmission designation.

Thereby, the minimum information required by the maintenance manager with respect to the apparatus 1 in which the problem has occurred, and the information on the customer A can easily and securely be transmitted to the maintenance manager Q as the pre-designated transmission destination without giving any burden onto the customer. Therefore, the maintenance manager can quickly obtain the accurate information on the apparatus 1 in which the problem has occurred, and a period for solving the problem can be shortened.

Particularly, when the optional information selected from the information (log) of the operation history of the apparatus 1, the information (ini file) having the operation condition of the apparatus 1 set therein, and the image information of the existing image of the apparatus 1 is attached, the maintenance manager can check the same information as that in the personal computer 3 of the customer side in the personal computers 15, 16 of the manufacturing sales company side. The apparatus 1 having the problem occurred therein can sufficiently be analyzed at an early stage without going to the customer side.

Moreover, when the user as the customer A starts the support mail software, the personal computer 3 prompts (urges) the input of the message information indicating the content of the transmission information, and further prompts the selection of the information to be attached to the message information from the information (log) of the operation history of the apparatus 1 having the problem occurred therein, the information (ini file) having the operation condition of the apparatus 1 set therein, and the image information of the existing image of the apparatus 1. The user simply operates the computer and presses the transmit button 36 in accordance with the types “TYPES 1 to 7” of the transmission content of the mail. Therefore, the user can transmit the information of the apparatus 1 having the problem occurred therein to the maintenance manager Q of the manufacturing sales company, without knowing expertise such as a method of storing the log in the floppy disk, a method of checking the content of the error dialog of the apparatus 1, and a method of checking the setting of the operation condition of the apparatus 1.

Furthermore, even when the support mail software is installed in the personal computers 3, 9 of the customers A, B, the local area network (LAN) environments of the customers A, B are not changed, and the mail is simply transmitted to the pre-designated maintenance manager Q of the manufacturing sales company via the mail servers 7, 13 of the customers A, B. Therefore, a security level constructed in the customers A, B does not drop at all.

Moreover, the customer A presses/operates the image store button 47, the log store button 48, or the ini store button 49 in the main screen 20 by the clicking of the mouse or the selection operation by the keyboard. Thereby, the existing image of the apparatus 1 having the problem occurred therein, the log file, or the ini file is stored in the internal memory of the personal computer 3, so that a record of the transmission to the maintenance manager Q can be stored.

The above-described first embodiment may be modified as follows.

In the first embodiment, the user inputs the message information and selects the attached files such as the information (log) of the operation history of the apparatus 1 having the problem occurred therein and the ini file in accordance with the display content of the main screen 20, presses/operates the transmit button 36 and thereby transmits the mail. However, when some problem occurs in the apparatus 1, the notice of the problem is received and the support mail software is automatically started. Subsequently, the attached files such as the message information, the information (log) of the operation history of the apparatus 1 having the problem occurred therein, and ini file are automatically prepared, and stored in the internal memory of the personal computer 3. The stored mail may automatically be transmitted to the maintenance manager Q of the pre-designated manufacturing sales company. Alternatively, the user may check the stored mail, press/operate the transmit button 36 and transmit the mail with a single click.

Moreover, the information (recipe) of the operation procedure of the apparatus 1 may be selected as the attached file in the transmission content 23, and a recipe store button for storing the information (recipe) of the operation procedure of the apparatus 1 in the internal memory of the personal computer 3 may be displayed in the main screen 20.

Furthermore, in the first embodiment, the example in which the customers A, B transmit the mail to the maintenance manager Q of the manufacturing sales company has been described. However, this is not limited, and the respective customers A, B may transmit the history of the operation of the apparatus, and the like, or the information such as the ini file to a service division for maintenance and inspection. Moreover, when there is no problem in security, it is also possible to notify the cellular phone of the maintenance manager Q of the information of problem occurrence and customer information and to receive the information by a mobile personal computer having a support mail program incorporated therein via the cellular phone.

Additionally, the apparatuses 1, 2 are not limited to visual examination apparatuses, and various microscope apparatuses, manufacturing line apparatus, and other apparatuses using the personal computer may also be used. Moreover, the problems of the personal computers 3, 9 may also be handled without connecting the apparatuses 1, 2 to the personal computers 3, 9.

A second embodiment of the present invention will next be described. The whole constitution of the notification system of the operation information according to the second embodiment is the same as that of FIG. 1 according to the first embodiment. The function of the personal computer 3 of the customer A will be described hereinafter, and the description of the function of the personal computer 9 of the customer B is omitted.

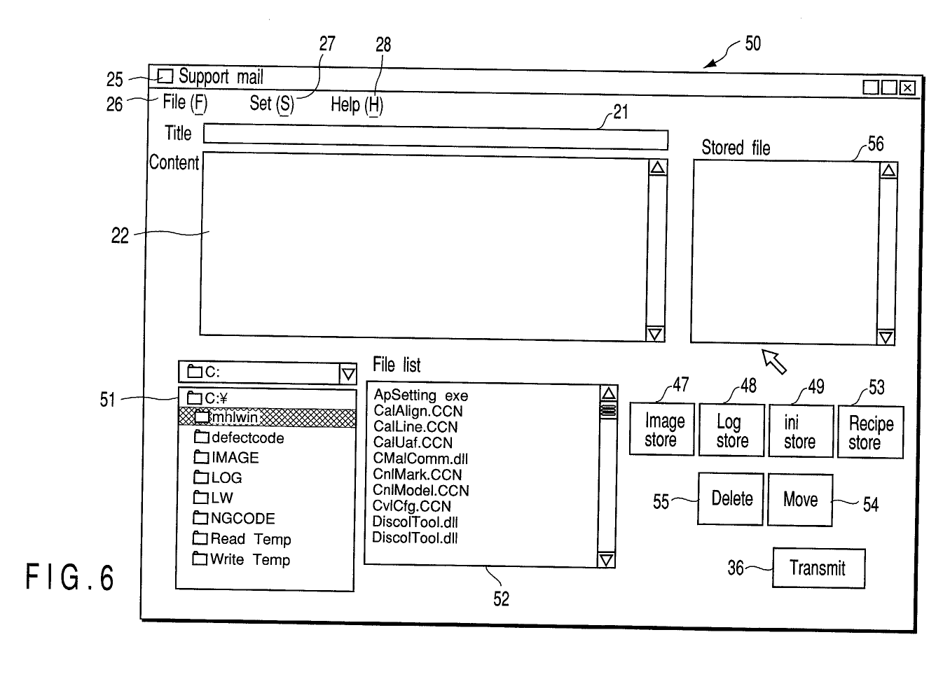

FIG. 6 is a diagram showing the main screen displayed in the notification system. When the incorporated support mail software is started, the computer main body 4 of the personal computer 3 of the customer A displays a main screen 50 for prompting the input of the information shown in FIG. 6 in the liquid crystal display 5.

The user performs the input operation by the mouse or the keyboard (not shown) connected to the computer main body 4 in accordance with the content of the main screen 50. Then, the computer main body 4 adds the information on the user of the apparatus 1, and the information on the apparatus 1 and personal computer 3 to the message information indicating the content of the transmission information. Furthermore, the computer main body 4 attaches the optional information selected from the information (recipe) of the operation procedure of the apparatus 1, the information (log) of the operation history of the apparatus 1, the information (ini file) having the operation condition of the apparatus 1 set therein, and the image information (such as the operation screen of the apparatus, and the image of a defective portion) picked up by the image pick-up apparatus 6 to the message information. Moreover, the computer main body 4 transmits the information to the mail server 14 of the maintenance manager Q as the pre-designated transmission destination.

As shown in FIG. 6, the main screen 50 displays the title box 21 for inputting the title of the mail, the content box 22 for inputting the message information (the text of the mail) indicating the content of the transmission information, a directory box 51 displaying a directory for selecting an optional holder from the storage unit 4a of the personal computer 3, and a file list box 52 displaying a list of file names in the holder selected in the directory box 51. Additionally, in the storage unit 4a, the files such as the information (recipe) of the operation procedure of the apparatus 1, the information (log) of the operation history of the apparatus 1, and the image information picked up by the image pick-up apparatus 6 are classified and stored in corresponding holders.

Moreover, similarly as the first embodiment, the main screen 50 displays the file menu 26, set menu 27, and help menu 28 in the menu bar 25. Furthermore, in the right part of the main screen 50, the image store button 47, log store button 48, ini store button 49, recipe store button 53, file move button 54, file delete button 55, transmit button 36, and stored file box 56 are displayed. When the user selects/operates the image store button 47, log store button 48, ini store button 49, and recipe store button 53 by the mouse or the keyboard, the files of the image information picked up by the image pick-up apparatus 6, log, ini file, and recipe are individually stored in the internal memory of the personal computer 3. The list of the file names of the respective files individually stored in the internal memory of the personal computer 3 is displayed in the stored file box 56.

Furthermore, when the user operates the file move button 54 by the mouse or the keyboard, the optional file selected in the file list box 52 is stored in the internal memory of the personal computer 3. Additionally, when the user operates the file delete button 55 by the mouse or the keyboard, the optional file selected in the stored file box 56 is deleted from the internal memory of the personal computer 3.

Additionally, the existing image, log, ini file, and recipe have file names ‘year month day hour minute second cap.lzh’, ‘year month day hour minute second log.lzh’, ‘year month day hour minute second ini.lzh’, and ‘year month day hour minute second recipe.lzh’, respectively, when compressed.

The transmit button 36 transmits the title of the mail set on the main screen 50, the message information indicating the content of the transmission information, the combination of the log of the apparatus 1, ini file of the apparatus 1, recipe of the apparatus 1, and existing image information of the apparatus 1 as the attached file of the message information, the information set in the dialog box 29 of the mail setting, and the information set in the dialog box 37 of the apparatus information setting to the mail server 14 of the maintenance manager Q.

The action of the notification system constituted as described above will next be described. When a certain problem occurs in the apparatus 1 in the operating state of the apparatus 1, the user starts the support mail software of the personal computer 3 in order to repair the problem of the apparatus 1 in the early stage.

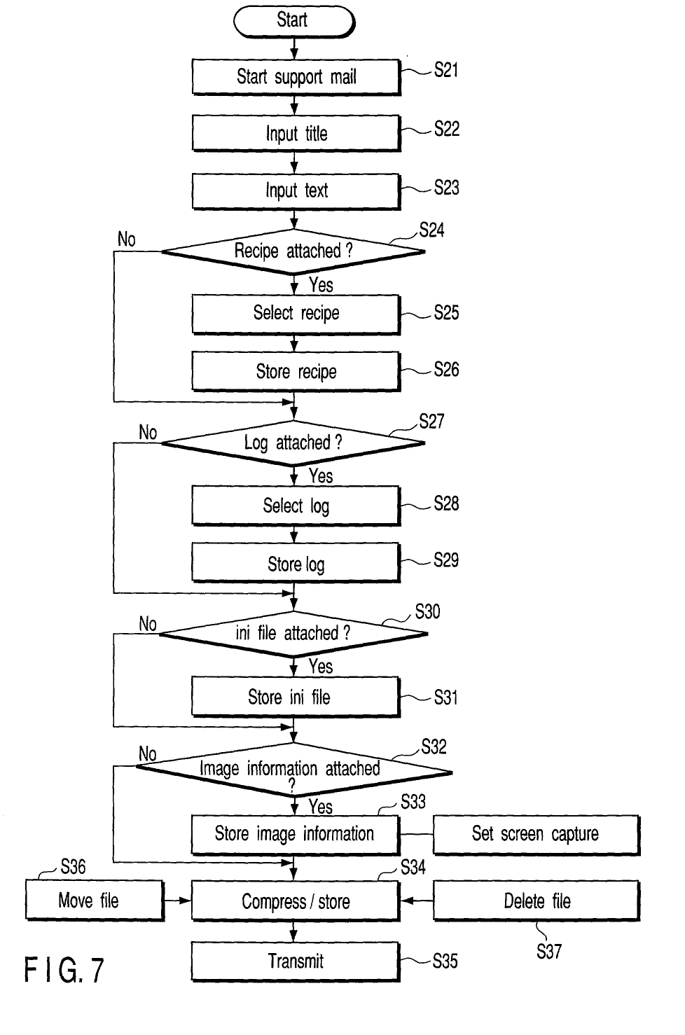

FIG. 7 is a flowchart showing the operation procedure of the personal computer 3 by support mail software. In the personal computer 3, when the support mail software is started in step S21, the main screen 50 shown in FIG. 6 is displayed in the liquid crystal display 5.

Here, it is assumed that the mail setting shown in FIG. 3 and the setting of the apparatus information shown in FIG. 4 are already ended in the support mail software. The personal computer 3 advances to the next step S22, and temporarily stores the inputted title of the mail in the internal memory, when the user inputs the title of the mail in the title box 21 of the main screen 50. In the next step S23, the personal computer 3 temporarily stores the inputted message information (the text of the mail) in the internal memory, when the user inputs the message information (the text of the mail) in the content box 22 of the main screen 50.

Next in step S24, when the file of recipe needs to be attached, the user selects the holder having the recipe stored therein from the directory box 51, and selects the necessary file of recipe from the file list box 52 by the mouse or the keyboard (not shown) in step S25. In this case, it is possible to select a plurality of files when the selection operation is performed several times. Subsequently in step S26, the user presses/operates the recipe store button 53 by the mouse or the keyboard, so that the selected files of recipes are temporarily stored in the internal memory.

When it is unnecessary to attach the file of the recipe in the step S24, or when it is necessary to attach the file of the log in step S27 after the step S26, the user selects the holder having the log stored therein from the directory box 51, and further selects the necessary file of log from the file list box 52 by the mouse or the keyboard (not shown) in step S28. In this case, it is possible to perform the selection operation a plurality of times and to select a plurality of logs. Next in step S29, when the user presses/stores the log store button 48 by the mouse or the keyboard (not shown), the selected files of logs are temporarily stored in the internal memory.

When it is unnecessary to attach the file of the log in the step S27, or when it is necessary to attach the ini file in step S30 after the step S29, the user presses/operates the ini store button 49 by the mouse or the keyboard in step S31, and the ini file of the apparatus 1 is obtained and temporarily stored in the internal memory.

When it is unnecessary to attach the ini file in the step S30, or when it is necessary to attach the file of image information in step S32 after the step S31, the user presses/operates the image store button 47 by the mouse or the keyboard in step S33, the color number and capture range are set as the screen capture, and the information of the existing image taken from the image pick-up apparatus 6 is temporarily stored in the internal memory.

When it is unnecessary to attach the file of the image information in the step S32, or after the step S33, the personal computer 3 compresses the file of recipe, the file of log, the ini file, and the information of the existing image temporarily stored in the internal memory, attaches these to the message information (the text of the mail), and stores the files in the predetermined region of the internal memory in step S34. The file names of the files stored in the internal memory are displayed in the stored file box 56.

Next, when the user presses the transmit button 36 by the operation of the mouse or the keyboard, in the step S35 the personal computer 3 automatically adds the respective information set in the dialog box 29, and the respective information set in the dialog box 37 to the title of the mail, the message information (the text of the mail), the compressed file of recipe, the file of log, the ini file, and the information of the existing image, and transmits the information to the mail server 14 of the maintenance manager Q side. Thereby, the information is sent to the mail server 14 of the maintenance manager Q side from the mail server 7 via the communication network 8.

The mail server 14 transfers the received information to the respective personal computers 15, 16. These personal computers 15, 16 display the information transferred from the mail server 14 in the respective liquid crystal displays.

Additionally, before the transmission in the step S35, in step S36 the user selects the optional file in the storage unit 4a by the mouse or the keyboard, and presses/operates the file move button 54, and the file can additionally be stored in the predetermined region of the internal memory. Moreover, before the transmission in the step S35, in step S37 the user selects the optional file displayed in the stored file box 56 by the mouse or the keyboard, and presses/operates the file delete button 55, and the file can be removed from the predetermined region of the internal memory.

As described above, in the second embodiment, at least the information on the user of the apparatus 1 of the customer A and the information on the apparatus 1 are added to the message information indicating the content of the transmission information. Furthermore, the selected information (recipe) of the operation procedure of the apparatus 1, the selected information (log) of the operation history of the apparatus 1, the information (ini file) having the operation condition of the apparatus 1 set therein, and the information of the existing image of the apparatus 1 are optionally attached. The information is transmitted to the maintenance manager Q as the pre-designated transmission destination.

Thereby, when the maintenance manager Q instructs the customer A to transmit, by telephone or the like, the information necessary for a solution with respect to the apparatus 1 having the problem occurred therein, the customer A can extract the files required by the maintenance manager Q, and transmit the files to the maintenance manager Q with a simple operation of the personal computer 3. That is, the minimum necessary information on the apparatus 1 having the problem occurred therein and the information on the customer A can be transmitted to the maintenance manager Q as the pre-designated transmission destination without burdening the customer. Therefore, the communication amount related to the transmission can be suppressed, and a period of the solution with respect to the apparatus 1 having the problem occurred therein can be shortened.

The present invention is not limited to the above-described embodiments, and can appropriately be modified and carried out within a range in which the scope is not changed. In the first or second embodiment, when the support mail software is started, the flowchart for inputting the title of the mail (title input) and inputting the message information (text input) is executed, but can also be executed immediately before the transmission. In this case, when the transmit button 36 of the main screen 20 or 50 is pressed/operated, the dialog boxes of the title box 21 and content box 22 are displayed. Thereafter, when a check button (not shown) is pressed/operated, the transmission is executed.

According to the present invention, there can be a notification method and notification system of operation information of an apparatus, in which the information required by a maintenance manager with respect to an apparatus having a problem occurred therein and the information on a customer can easily and securely be transmitted to the maintenance manager as a pre-designated transmission destination without giving any burden to a customer side. Moreover, the maintenance manager can quickly obtain accurate information with respect to the apparatus having the problem occurred therein by the information transmitted from the customer, and a period for solving the problem can be shortened.

Moreover, according to the present invention, there can be provided a storage medium readable by a computer, in which a program is stored to transmit accurate information on the apparatus having the problem occurred therein and the information on the customer to the maintenance manager as the pre-designated transmission destination without burdening the customer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A notification method of operation information of an apparatus, comprising:
adding at least one information of information on a user of an object apparatus, information of an operation procedure of said object apparatus concerning a problem having occurred in said object apparatus, information of an operation history of said object apparatus, information in which an operation condition of said object apparatus is set, and information of an existing image of said object apparatus to message information indicating a content of transmission information; and
transmitting the at least one information to a terminal apparatus of a pre-designated transmission destination from a terminal apparatus of a transmitter via a communication line.

2. The notification method of the operation information of the apparatus according to claim 1, wherein the information on the user of said object apparatus comprises at least a name, a mail address, and mail server information of said user.

3. The notification method of the operation information of the apparatus according to claim 1, wherein the information on the user of said object apparatus includes at least two of a name of said user and a formal name of said object apparatus among the name of said user, the formal name of said object apparatus, a manufacture number of said object apparatus, a temporary name of said object apparatus, and a delivery date of said object apparatus.

4. The notification method of the operation information of the apparatus according to claim 1, wherein said object apparatus comprises an image pick-up apparatus which picks up an image of an examination object, and is an examination apparatus which processes and examines the image picked up by the image pick-up apparatus.

5. The notification method of the operation information of the apparatus according to claim 4, wherein the existing image of said object apparatus is an image picked up from said examination object by a predetermined image pick-up apparatus.

6. The notification method of the operation information of the apparatus according to claim 1, wherein the existing image of said object apparatus is an image obtained by photographing said object apparatus with a predetermined monitor camera.

7. A notification method of operation information of an apparatus, comprising:
connecting a terminal apparatus which controls and monitors an object apparatus installed on a customer side to a terminal apparatus of a maintenance side via a communication circuit;
prompting input of message information indicating a content of transmission information based on a notification program recorded in the terminal apparatus of said customer side;
displaying a screen which prompts selection of a transmission content to be attached to said message information from a plurality of transmission contents including at least one of information of an operation history of the object apparatus, information having an operation condition of said object apparatus set therein, and information of the existing image of said object apparatus; and
displaying a transmission button which prompts attachment of the information on said object apparatus corresponding to the selected transmission content in the screen to said message information and transmission of the information to the pre-designated terminal apparatus of the maintenance side.

8. The notification method of the operation information of the apparatus according to claim 7, further comprising: displaying a storage button which prompts storage of any one of the information of the operation history of said object apparatus, the information having the operation condition of said object apparatus set therein, and the information of the existing image of said object apparatus.

9. The notification method of the operation information of the apparatus according to claim 7, further comprising: displaying a directory screen indicating a stored state of the information on said object apparatus recorded in the terminal apparatus of said customer side; and displaying a list of the information in a holder including the information of the operation history of said object apparatus, the information having the operation condition set therein, and the information of the existing image selected in the directory screen.

10. A notification method of operation information of an apparatus, comprising:
receiving message information indicating a content of transmission information from a terminal apparatus of a customer side connected via a communication line, information on a user of an object apparatus, added to the message information, and at least one information of information of an operation procedure of said object apparatus concerning a problem occurred in said object apparatus, information of an operation history of said object apparatus, information having an operation condition of said object apparatus set therein, and information of an existing image of said object apparatus by a terminal apparatus of a maintenance side; and
displaying these information in a display of the terminal apparatus of said maintenance side in order to analyze an operation of said object apparatus.

11. The notification method of operation information of an apparatus according to claim 10, wherein the terminal apparatus of said maintenance side is a mobile personal computer having a communication function, and can receive the information from the terminal apparatus of said customer side via said communication line.

12. A notification method of operation information of an apparatus, comprising:
monitoring an operation state of an object apparatus installed on a customer side with a terminal apparatus of said customer side, and automatically storing at least one of information of an operation history of said object apparatus concerning a problem, and information having an operation condition of said object apparatus set therein in said terminal apparatus of said customer side, when the problem occurs in the object apparatus; and
automatically transmitting the stored information to a pre-designated terminal apparatus of a maintenance side via a communication line.

13. A notification system of operation information of an apparatus, comprising:
a customer-side terminal apparatus which adds at least one information of information on a user of an object apparatus, information of an operation procedure of said object apparatus concerning a problem occurred in said object apparatus, information of an operation history of said object apparatus, information having an operation condition of said object apparatus set therein, and information of an existing image of said object apparatus to message information indicating a content of transmission information, and transmits these information to a pre-designated transmission destination from a terminal apparatus of a transmitter via a communication line; and
a maintenance-side terminal apparatus which receives said message information transmitted from the customer-side terminal apparatus, and the information on the user of said object apparatus and the information on said object apparatus, added to the message information, and displays these information in order to analyze an operation of said object apparatus.

14. The notification system of the operation information of the apparatus according to claim 13, wherein said customer-side terminal apparatus monitors an operation state of said object apparatus, and
stores at least one of the information of the operation procedure of said object apparatus concerning the problem occurred in said object apparatus, the information of the operation history of said object apparatus, the information having the operation condition of said object apparatus set therein, and the information of the existing image of said object apparatus.

15. The notification system of the operation information of the apparatus according to claim 13, wherein said customer-side terminal apparatus has a function of:
selecting information to be attached to said message information indicating the content of the transmission information from the information of the operation procedure of said object apparatus, the information of the operation history of said object apparatus, the information having the operation condition of said object apparatus set therein, and the information of the existing image of said object apparatus; and
transmitting said message information and the selected information to said pre-designated transmission destination.

16. A storage medium which stores a computer readable program, the program comprising:
prompting input of message information indicating a content of transmission information;
adding information on a user of an object apparatus and information on said object apparatus to said inputted message information;
prompting transmission of these information to a pre-designated transmission destination; and
transmitting said message information and the information added to said message information to said transmission destination.

17. The storage medium according to claim 16, which stores the computer readable program, the program comprising:
displaying a screen which prompts selection of a transmission content to be added to said message information from a plurality of transmission contents including at least one of information of an operation history of said object apparatus, information having an operation condition of said object apparatus set therein, and information of an existing image of said object apparatus; and
adding the selected information to said message information and transmitting the information to said transmission destination.

18. A storage medium which stores a computer readable program, the program comprising: receiving a problem notice with respect to an object apparatus installed in a customer side; automatically preparing an attached file of information of an operation history and information having an operation condition set therein concerning said object apparatus; and automatically transmitting said attached file together with information on a user of said object apparatus to a pre-designated maintenance-side terminal apparatus.
